(19) United States
(12) Patent Application Publication
(10) Pub. No.: US 2010/0327382 A1
(43) Pub. Date: Dec. 30, 2010

(54) High Bandwidth, Monolithic Traveling Wave Photodiode Array

(75) Inventors: Joe C. Campbell, Charlottesville, VA (US); Andreas Beling, BONN (DE); Huapu Pan, Charlottesville, VA (US)

Correspondence Address: UNIVERSITY OF VIRGINIA PATENT FOUNDATION, 250 WEST MAIN STREET, SUITE 300, CHARLOTTESVILLE, VA, 22902, US

(73) Assignee: UNIVERSITY OF VIRGINIA PATENT FOUNDATION, Charlottesville, VA (US)

(21) Appl. No.: 12/822,518

(22) Filed: Jun. 24, 2010

Related U.S. Application Data
(60) Provisional application No. 61/220,365, filed on Jun. 25, 2009.

(51) Int. Cl. H01L 31/12; H01L 31/18

(52) U.S. Cl. 257/432; 438/24; 257/E33.077; 257/E31.127

(57) ABSTRACT

The monolithic application of a high speed TWPDA with impedance matching. Use of the high speed monolithic TWPDA will allow for more efficient transfer of optical signals within analog circuits and over distances.

### CROSS-REFERENCE TO RELATED APPLICATIONS

The present application claims priority from U.S. Provisional Application Ser. No. 61/220,365 filed Jun. 25, 2009, entitled “Monolithic Photodiode Array with Impedance Match and Related Method;” of which is hereby incorporated by reference herein in its entirety.

### GOVERNMENT SUPPORT

Work described herein was supported by Federal Grant No. ONR Grant No. N000173-06-1-G004-, awarded by Office of Naval Research. The Government has certain rights in the invention.

### FIELD OF INVENTION

The present invention relates generally to the detection of high-power signals through the application of novel photodiode array geometry and circuit design.

### BACKGROUND OF INVENTION

Photodiodes employed as optical-to-electrical (O/E) converters with high bandwidth and large saturation photocurrents are key components in high-bit-rate optical fiber networks and photonic microwave applications. Ideally, in order to reach optimum receiver sensitivity and the optimum compression dynamic range, the photodiode (PD) would be operated in an optically pre-amplified receiver at high optical power levels to provide sufficient output photocurrent without any electrical post-amplification. However, in order to operate at high-speeds the PD design must have low capacitance and thus small area, limiting its power output.

High-speed analog optical links with large dynamic range require fast high-power photodiodes. Generally, for high-speed operation, the photodiode has to be designed for low capacitance and small carrier transit times. These considerations require a small active area in conjunction with thin drift layer thickness. However, for a given optical input power, the reduction in PD area results in higher photocurrent densities and saturation effects owing primarily to space charge effects become more pronounced. Although an increase in reverse bias voltage may lead to improvement, thermal stress of the photodiode is increased as the dissipated power scales with bias voltage. As a result, space-charge effects leading to a saturated photocurrent become more pronounced when compared to large area devices.

In effect, prior art has required a tradeoff between photodiodes (PDs) capable of high-speed signal detection and high power output. This meant that in order to obtain a useful signal capable of driving an external load electrical amplification was required at high speeds (due to the need for small area PDs). Such electrical amplification requires significant additional power and manufacturing and can result in a delayed or blurred signals at high speeds. Thus a solution was required to overcome this tradeoff.

### SUMMARY OF THE INVENTION

One novel approach to overcoming the trade-off between high speed and large saturation current is to distribute symmetrically the optical signal to several photodiodes and combine their photocurrents by means of a transmission line. In this configuration the optical signal is split by a power divider and fed into several discrete photodiodes, which are connected by an output transmission line. Due to the uniform optical power distribution, the photocurrent flowing through each photodiode scales inversely with the number of PDs. By embedding the discrete PDs within a transmission line, a traveling wave photodiode array (TWPDA) is formed.

An embodiment of the present invention comprises a monolithic approach including photodiodes connected by air bridges (or some type of bonding connector or wire) to a coplanar stripline (CPS) on a substrate (or some type of submount). One embodiment of the present invention comprises integrated, vertical illuminated photodiodes, in one embodiment back-illuminated PDs, a coplanar waveguide transmission line and a termination resistor on the same chip comprising a semi-insulating substrate. By doing so, this embodiment of the present invention realizes the advantages of a very compact design, achieves an excellent impedance match to the load resistor, increases repeatability, avoids bonding wires and parasitics and hence can increase bandwidth and overall performance.

One embodiment of the present invention, by appropriate design of the discrete photodiodes, the spacing between adjacent photodiodes d and the transmission line geometry the characteristic impedance of the photodiode array can be brought to within 50 Ω of the external load. Since the frequency response is not limited by the overall resistance-capacitance time constant the bandwidth of the single photodiode can be retained, to a large extent, within the Bragg limit.

In one embodiment, a monolithically integrated TWPDA based on back-illuminated high-power modified uni-traveling carrier (MUTC) photodiode, a 2-element array with 40 μm photodidoes (PDs) and integrated matching resistor achieved a high saturation current of 114 mA at −3.5 V and a 3 dB bandwidth of 17 GHz. Compared to a single lumped element 40 μm-PD this corresponds to almost two times the saturation current and 85% of the bandwidth. Further embodiments suggest that TWPDAs with >2 elements lead to further improvements in saturation current at maintained bandwidth.

An aspect of an embodiment of the present invention provides a monolithic structure. The structure may comprise an array of photodiodes arranged linearly within the structure such that each of the photodiode that may be placed at a regular interval to create a circuit. Further, the photodiodes may have an electrical output, wherein each electrical output of the photodiodes may be connected to the electrical output of each adjacent photodiode by a linear output transmission line. Further, the photodiodes may have an electrical input, wherein each electrical input of the photodiodes may be connected to the electrical input of each adjacent photodiodes by a linear input transmission line. Moreover, the linear output transmission line and the linear input transmission line may be connected to each other on a first end of the array by a resistor and an isolating capacitor may be embedded within the structure. Still yet, the linear output transmission line and the linear input transmission line may be connected on a second end of the array to a load external to the substrate.

The linear output transmission and the linear input transmission line may be configured to form a high-speed microwave coplanar waveguide. The photodiodes may be optimized for high power, such that each has a high saturation photocurrent. In an approach, the circuit has a total impedance, adjusted by the resistor on the first end of the array, photodiode geometry and transmission line geometry, may be equal to the total impedance of the external load. The structure may have an optical input signal that is in communication with an optical waveguide network designed to stagger the optical input signal to each of photodiode such that the electrical output from each photodiode reaches the external load at the same time. The optical waveguide may include a power divider set to separate and channel the optical input signal into individual optic lines paired in a one to one ratio with each the photodiode. Moreover, the optic lines may vary in length and refractive index, such that each of the optic line delays the optical input signal at regular intervals causing the electrical output from each photodiode to reach the external load at the same time. The electrodes may be placed around each of the optic lines within the optical waveguide such that the refractive index of each optic line may be altered individually by activating the electrodes.

An aspect of an embodiment of the present invention provides a monolithic application of a high speed TWPDA with impedance matching. The use of the high speed monolithic TWPDA will allow for, among other things, more efficient transfer of optical signals within analog circuits and over distances.

It should be appreciated that an aspect of an embodiment of the present invention may include any method or technique used or adapted for manufacturing the monolithic structure discussed throughout this disclosure.

In addition, the monolithic design is more compact and easily integrated into larger equipment. These advantages constitute a significant improvement over prior art.

### BRIEF DESCRIPTION OF DRAWINGS

The accompanying drawings, which are incorporated into and form a part of the instant specification, illustrate several aspects and embodiments of the present invention and, together with the description herein, serve to explain the principles of the invention. The drawings are provided only for the purpose of illustrating select embodiments of the invention and are not to be construed as limiting the invention.

FIG. 1 is a CAD layout schematic diagram of a 2-element TWPDA with integrated load matching resistors.

FIG. 2 is a CAD layout schematic diagram of a 8-element TWPDA with integrated load matching resistors.

FIG. 3 is a CAD layout schematic diagram of a 2-element TWPDA with integrated load matching resistors, expanded and labeled for clarity.

FIG. 4 is a schematic diagram of an optical waveguide.

### DETAILED DESCRIPTION OF THE INVENTION

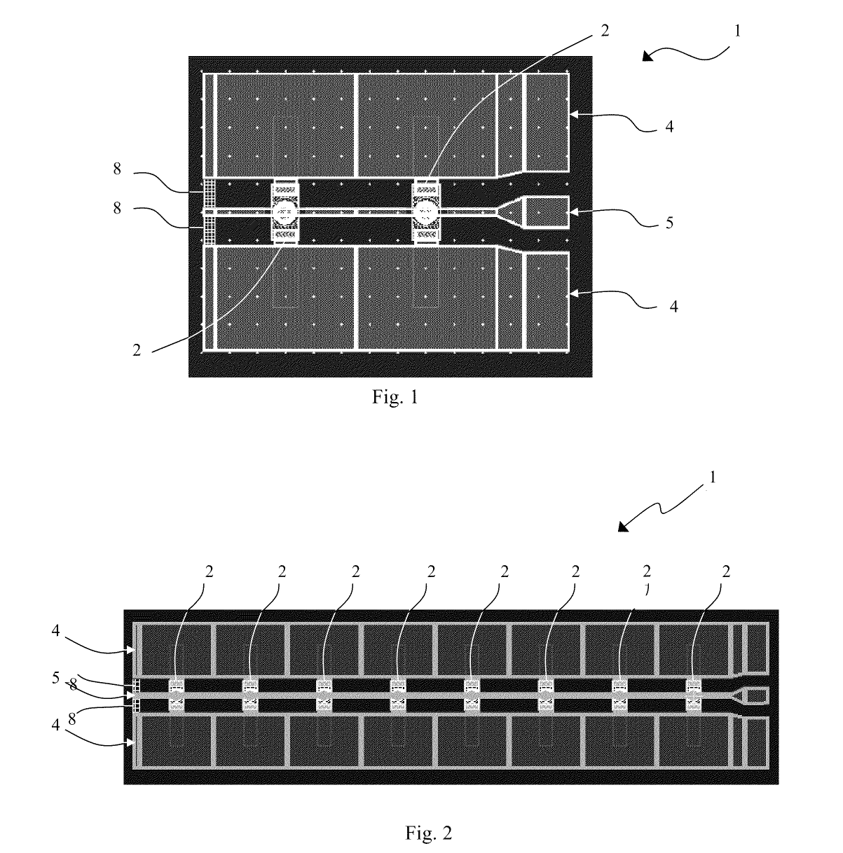

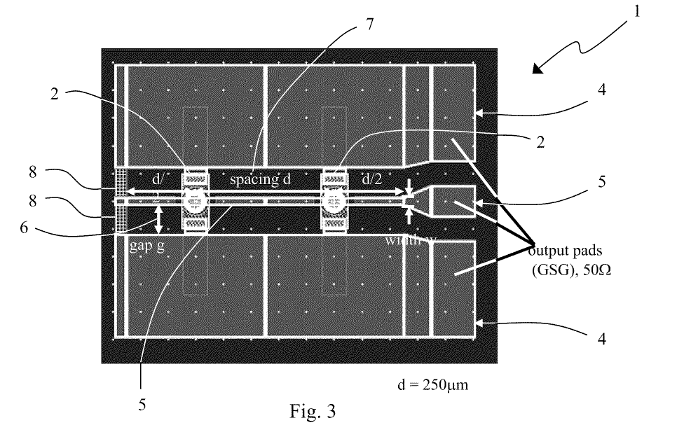

Referring to FIGS. 1-3, an embodiment of the present invention may comprises a 2-element TWPDA chip 1 comprising two back-illuminated photodiodes 2, each may have an active area diameter of 40 μm and comprising a vertical layer stack corresponding to a charge compensated MUTC PD with both absorbing and non-absorbing depleted regions. The photodiodes 2 comprise InGaAs absorber region with a thickness of 850 nm and a 200 nm depleted n⁻ layer and four step-graded p-doped layers ranging from 2.5·10¹⁷ to 2·10¹⁸ cm⁻³. Furthermore, electron drift layer is comprised of slightly n-type doped 605 nm InP for space charge compensation. Photodiode 2 further comprise n- and p-type contact layers, formed by a highly doped InP and a 50 nm InGaAs layer, respectively. Coplanar waveguide (CPW) transmission line 4 collects the electrical output (such as output signal or the like as desired or required), which connects the photodiodes 2 in parallel. The width of the CPW transmission line 4 center conductor 5 and the gap 6 were 17 μm and 50 μm, respectively. It should be appreciated that the dimensions of the Chip 1 and it's associated components may vary as desired or required. The CPW transmission line 4 impedance Z_{L} is calculated to be 75 Ω.

The integration of the photodiodes 2 within the CPW transmission line 4 leads to an additional capacitive loading of the transmission line due to photodiode's 2 junction capacitance. Given the photodiode's 2 capacitance of 170 fF determined from capacitance-voltage measurements and the spacing 7 between adjacent photodiodes of d=250 μm, we derived a TWPD characteristic impedance of 28 Ω. The electrical Bragg frequency was estimated to be >50 GHz. Since reflections of the backward propagating microwave signal at the input of the transmission line lead to a reduced bandwidth, 30 Ω termination resistor 8 was integrated. The termination resistor 8 may consist of two resistors in parallel each with a nominal value of 60 Ω. In an approach the resistors 8 may be matching resistors (2×100 Ω).

The fabrication process may start with the epitaxial layer structure, which was grown on semi-insulating double-side-polished InP substrates by metal-organic-chemical vapor deposition. Back-illuminated mesa photodiodes 2 were structured by wet-chemical etching. The termination resistor 8 were formed by evaporation of a 100 nm-thick Ti layer on InP substrate. Finally the contact pads for microwave probing and air-bridge connections for CPW transmission line 4 were implemented on top of a SiO₂ passivation layer, involving evaporation of Ti/Pt/Au and electro-plating. A layer of SiO₂ was deposited on the back of the wafer as an antireflection coating.

In some embodiments of the present invention, for applications below 40 GHz, vertically illuminated PDs are generally favored over their waveguide and waveguide-integrated counterparts, which often require elaborate fabrication processes and more complex fiber-chip coupling. Another advantage of back-illuminated photodiodes is their higher bandwidth-efficiency product since double-path absorption can be exploited. An embodiment of the present is a monolithically integrated TWPDA with a 17 GHz bandwidth. The 2-element TWPDA 1 with integrated termination resistor 8 is based on back-illuminated high-power MUTC photodiodes. In this approach, a phase match of the propagating RF photocurrents from different PDs in the array is achieved by an externally controlled time-delayed optical feed.

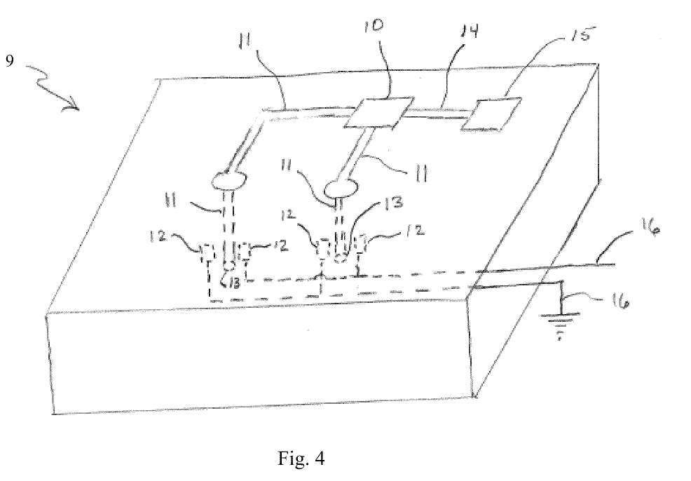

Turning to FIG. 4, in some embodiments of the invention, an optical waveguide network 9 may be used to further tune the signal timing. In the demonstrated embodiment, the optical waveguide network 9 comprising power divider 10, fiber optic wires 11, electrodes 12 dispersed around the optic wires 11, optical input receiver 15, optical output 13, optical input line 14, and electrode input signal 16. It should be appreciated that the optic wires may be fiber optic or any other material capable of transmitting optical signals. In any embodiment of the optical waveguide 9, the number of fiber optic wires 11 and electrodes 12 should correspond proportionally to the number of photodiodes 2 contained in the complimenting TWPDA, which is TWPDA chip 1 in the present embodiment. The output of each fiber optic line or wire 11 terminates at regular intervals also corresponding to the TWPDA interval, spacing 7 (denoted as “d”) in an embodiment of the present embodiment. In an embodiment, optical waveguide 9 may be placed over TWPDA chip 1 in order to align the output signals of photodiodes 2.

While the described embodiment comprises one working model of the present invention, many different iterations are possible, both with and without the optical waveguide. Materials used in the described embodiment may be varied along with the number of PDs, terminal resistors and other components to achieve the desired characteristics for the application intended.

The devices, systems, compositions and methods of various embodiments of the invention disclosed herein may utilize aspects disclosed in the following references, applications, publications and patents and which are hereby incorporated by reference herein in their entirety:

1. Goldsmith et al.: “Principles and Performance of Traveling-Wave Photodetector Arrays”, in IEEE Transactions On Microwave Theory and Techniques, Vol. 45, No. 8, August 1997, pp. 1342.

2. E. L. Ginzton et al.: “Distributed Amplification”, in Proceedings of the I.R.E., August 1948, pp. 956.

3. U.S. Pat. No. 6,906,308 B2, Yasuoka, et al., “Semiconductor Light Receiving Device in Which Optical and Electric Signal are Propagated at Matched Velocities”, Jun. 14, 2005.

4. U.S. Pat. No. 6,528,776 B1. Marsland, R., “Electro Optic Converter Having a Passive Waveguide and Exhibiting Impedance Mismatch”, Mar. 4, 2003.

5. U.S. Pat. No. 5,572,610, Toyohara, A., “Waveguide-Type Optical Device and Impedance Matching Method Thereof”, Nov. 5, 1996.

6. Andreas Beling et al. “High Power Monolithically Integrated Traveling Wave Photodiode Array,” in IEEE Photonics Tech. Letters, Vol. 21, No. 24, Dec. 15, 2009, pp. 1813

What is claimed is:

1. A monolithic structure, said structure comprising:
an array of photodiodes arranged linearly within said structure such that each of said photodiode is placed at a regular interval to create a circuit;
said photodiodes having an electrical output, wherein each electrical output of said photodiodes is connected to the electrical output of each adjacent photodiode by a linear output transmission line;
said photodiodes having an electrical input, wherein each electrical input of said photodiodes is connected to the electrical input of each adjacent photodiodes by a linear input transmission line;
wherein said linear output transmission line and said linear input transmission line are connected to each other on a first end of said array by a resistor and an isolating capacitor embedded within said structure; and
wherein said linear output transmission line and said linear input transmission line are connected on a second end of said array to a load external to the substrate.

2. The structure of claim 1, wherein the said linear output transmission and said linear input transmission line form a high-speed microwave coplanar waveguide.

3. The structure of claim 1, wherein said photodiodes are optimized for high power, such that each has a high saturation photocurrent.

4. The structure of claim 1, wherein said circuit has a total impedance, adjusted by said resistor on the first end of the array, photodiode geometry and transmission line geometry, that is equal to the total impedance of said external load.

5. The structure of claim 1, wherein said structure has an optical input signal that is in communication with an optical waveguide network designed to stagger said optical input signal to each said photodiode such that said electrical output from each photodiode reaches said external load at the same time.

6. The structure of claim 5, wherein said optical waveguide includes a power divider set to separate and channel said optical input signal into individual optic lines paired in a one to one ratio with each said photodiode; and
wherein said optic lines vary in length and refractive index, such that each said optic line delays said optical input signal at regular intervals causing said electrical output from each photodiode to reach the external load at the same time.

7. The structure of claim 6, wherein electrodes are placed around each said optic line within said optical waveguide such that the refractive index of each optic line may be altered individually by activating said electrodes.

8. A method of manufacturing the monolithic structure according to any one of claims 1-7.
